(19) United States
(12) Patent Application Publication
(10) Pub. No.: US 2021/0098393 A1
(43) Pub. Date: Apr. 1, 2021

(54) SYSTEMS AND METHODS FOR ELECTRICAL CHARGE DISSIPATION

(71) Applicant: SEMICONDUCTOR COMPONENTS INDUSTRIES, LLC, Phoenix, AZ (US)

(72) Inventor: Min JANG, Meridan, ID (US)

(73) Assignee: SEMICONDUCTOR COMPONENTS INDUSTRIES, LLC, Phoenix, AZ (US)

(21) Appl. No.: 16/662,041

(22) Filed: Oct. 24, 2019

Related U.S. Application Data
(60) Provisional application No. 62/906,267, filed on Sep. 26, 2019.

(51) Int. Cl. H01L 23/60; H01L 27/146

(52) U.S. Cl. CPC H01L 23/60; H01L 27/1462; H01L 27/14685; H01L 27/14627; H01L 27/1463; H01L 27/14621

(57) ABSTRACT

A system and method of charge dissipation by embedded metal connection that includes an image sensor is disclosed. Specific implementations include a semiconductor substrate, an antireflective coating (ARC) layer coupled over the semiconductor substrate, a charge dissipation structure included within the ARC layer, and a passivation layer coupled over the ARC layer.

### CROSS REFERENCE TO RELATED APPLICATIONS

This application claims the benefit of the filing date of U.S. Provisional Patent Application 62/906,267, entitled “SYSTEMS AND METHODS FOR ELECTRICAL CHARGE DISSIPATION” to Min Jang, which was filed on Sep. 26, 2019, the disclosure of which is hereby incorporated entirely herein by reference.

### BACKGROUND

### 1. Technical Field

Aspects of this document relate generally to semiconductor sensors. More specific implementations involve image sensors.

### 2. Background

Semiconductor sensors are used in a variety of electronic devices, such as vehicles, smart phones, tablets, and other devices. Image sensors are a type of semiconductor sensor. Image sensors convert light striking a pixel into an electric signal. The electric signal may be processed using a digital signal processor to form an electronic image.

### SUMMARY

Implementations of an image sensor may include: a semiconductor substrate, an antireflective coating (ARC) layer coupled over the semiconductor substrate, a charge dissipation structure included within the ARC layer, and a passivation layer coupled over the ARC layer.

Implementations of image sensors may include one, all, or any of the following:

A color filter array may be coupled over the passivation layer.

A plurality of lenses may be coupled over the color filter array.

A hafnium oxide layer may be coupled over the ARC layer.

One of a backside deep trench isolation structure or a frontside deep trench isolation structure may be included within the semiconductor substrate.

The charge dissipation structure may include an electrically conductive metal.

The electrically conductive metal may be configured to collect electrostatic charges and to direct the electrostatic charges to a ground.

The charge dissipation structure may include a grid.

The charge dissipation structure may include a plurality of substantially parallel bars.

In various implementations, at least a portion of the charge dissipation structure may contact a grounded pad.

Implementations of a method of forming an image sensor may include: providing a semiconductor substrate, forming an antireflective coating (ARC) layer over the semiconductor substrate, and patterning the ARC layer to form a plurality of trenches therein. The method may also include forming a charge dissipation layer into the plurality of trenches, etching a pixel array area into the charge dissipation layer, and forming a passivation layer over the ARC layer.

Implementations of a method of forming an image sensor may include one, all, or any of the following:

The method may include forming a color filter array over the passivation layer.

The method may include forming a plurality of lenses over the color filter array.

The method may also include forming a hafnium oxide layer over the ARC layer, and using the hafnium oxide layer as an etch stop during etching the pixel array area into the charge dissipation layer.

The method may include etching a plurality of trenches in the semiconductor substrate, and filling each trench of the plurality of trenches with one of a polysilicon or an electrically conductive material to form one of a backside deep trench isolation structure or a frontside deep trench isolation structure.

The ARC layer may include at least a second layer coupled over a first layer and the method may further include extending one or more trenches of the plurality of trenches entirely through the first layer of the ARC layer.

Implementations of a method of forming an image sensor may include: providing a semiconductor substrate, forming an antireflective coating (ARC) layer over the semiconductor substrate, and forming an etch stop layer over the ARC layer. The method may also include patterning the ARC layer to form a plurality of trenches therein, forming a charge dissipation layer into the plurality of trenches, etching a pixel array area into the charge dissipation layer, and forming a passivation layer over the ARC layer.

Implementations of a method of forming an image sensor may include one, all, or any of the following:

The method may include forming a color filter array over the passivation layer, and forming a plurality of lenses over the color filter array.

The method may include etching a plurality of trenches in the semiconductor substrate, and filling each trench of the plurality of trenches with one of a polysilicon or an electrically conductive material to form one of a backside deep trench isolation structure or a frontside deep trench isolation structure.

The ARC layer may include at least a second layer coupled over a first layer and the method may further include extending one or more trenches of the plurality of trenches entirely through the first layer of the ARC layer.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a cross sectional view of an image sensor including an antireflective coating (ARC) layer;

FIG. 2 is a cross sectional view of the image sensor of FIG. 1 after the ARC layer has been patterned;

FIG. 3 is a cross sectional view of the image sensor of FIG. 2 after a metal layer has been formed;

FIG. 4 is a cross sectional view of the image sensor of FIG. 3 after a charge dissipation structure (layer) has been formed;

FIG. 5 is a cross sectional view of the image sensor of FIG. 4 including a color filter array;

FIG. 6 is a cross sectional view of the image sensor of FIG. 5 including a plurality of lenses;

FIG. 7 is a cross sectional view of the image sensor including two semiconductor die;

FIG. 8 is a cross sectional view of an implementation of an image sensor including a hafnium oxide layer;

FIG. 9 is a cross sectional view of the image sensor of FIG. 8 after an ARC layer has been patterned;

FIG. 10 is a cross sectional view of the image sensor of FIG. 9 after a metal layer has been formed;

FIG. 11 is a cross sectional view of the image sensor of FIG. 10 after a charge dissipation structure (layer) has been formed;

FIG. 12 is a cross sectional view of the image sensor of FIG. 11 including a deep trench isolation structure; and

FIG. 13 is a cross sectional view of the image sensor of FIG. 12 including a plurality of lenses.

### DESCRIPTION

This disclosure, its aspects and implementations, are not limited to the specific components, assembly procedures or method elements disclosed herein. Many additional components, assembly procedures and/or method elements known in the art consistent with the intended image sensor systems disclosed herein will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such image sensor systems, and implementing components and methods, consistent with the intended operation and methods.

The implementations of the charge dissipation structure of the image sensors and image sensor packages disclosed herein may be applied to either backside-illuminated (BSI) image sensors or front side-illuminated (FSI) image sensors. Particular implementations may include complimentary metal-oxide semiconductor (CMOS) image sensors, charge-coupled device (CCD) image sensors, or other image sensor types. The sensor packages disclosed herein may be chip-scale packages in various implementations. While this disclosure primarily refers to image sensors and image sensor packages, it is understood that the various principles disclosed herein may also be similarly applied to non-image sensor semiconductor packages in order to prevent damage/noise induced through electrostatic discharge (ESD) or electrostatic charging.

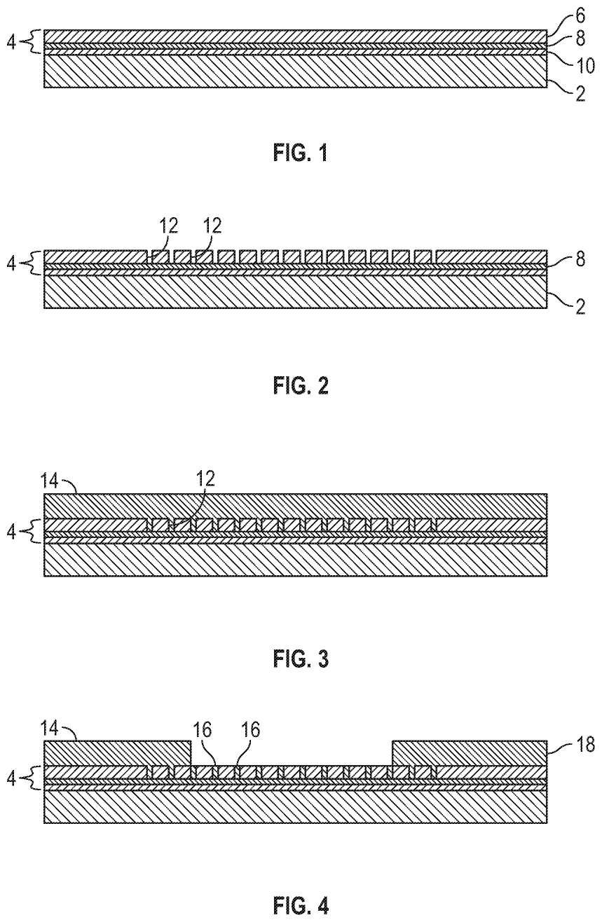

Referring to FIG. 1, a cross sectional view of an image sensor including an antireflective coating (ARC) layer is illustrated. As illustrated, an antireflective coating (ARC) layer 4 is formed, or coupled, over a semiconductor substrate 2. While a semiconductor substrate is referred to is this document, the semiconductor substrate (layer) in any implementation could be any type of semiconductor substrate including, by non-limiting example, a silicon layer, an epitaxial silicon layer, silicon-on-insulator, any combination thereof, or any other silicon-containing layer material. Further, it is also understood that in other implementations an alternative substrate or layer, other than a silicon-containing layer, may be used, such as, by non-limiting example, gallium arsenide, silicon carbide, sapphire, aluminum nitride, or a metal-containing layer may be used as a semiconductor substrate, in place of a silicon layer.

Still referring to FIG. 1, the ARC layer 4 may include a number of layers, as illustrated. In various implementations, the number of layers may vary; the ARC layer 4 may include a first layer 6, a second layer 8, and a third layer 10, though the number of layers may vary to any number of layers. In various implementations, the first layer 6 may include tantalum oxide (TaO). In various implementations, the second layer 8 may include hafnium oxide (HfO₂). In such implementations, the hafnium oxide may be configured to act as an etch stop. In various implementations, the third layer 10 may include aluminum oxide (Al₂O₃). In other various implementations, the layers may include other materials, such as silicon dioxide (SiO₂) and silicon nitride (SiN), as non-limiting examples.

Referring to FIG. 2, a cross sectional view of the image sensor of FIG. 1 after the ARC layer has been patterned is illustrated. As illustrated, the ARC layer 4 is coupled over the semiconductor substrate 2. After the ARC layer 4 has been patterned, a plurality of trenches 12 are formed within the ARC layer 4. As illustrated, and in implementations where the ARC layer 4 includes three layers, the ARC layer 4 is patterned, or etched, down to the second layer 8. As previously disclosed, the second layer 8 may include hafnium oxide, which may be configured to act as an etch stop, which then prevents the etching of the ARC layer 4 from proceeding past the second layer 8. In various implementations, the hafnium oxide layer may be used as an etch stop during the etching of a pixel array area into the charge dissipation layer.

Referring to FIG. 3, a cross sectional view of the image sensor of FIG. 2 after a metal layer has been formed is illustrated. As illustrated, a metal layer 14 is formed over the ARC layer 4 and into the plurality of trenches 12. In various implementations, the metal layer 14 may be deposited through sputtering, chemical vapor deposition, a combination of physical vapor deposition and chemical vapor deposition, spin coating, ink-jet printing, screen printing, or any other process of forming a layer on the material over the ARC layer 4 material.

Referring to FIG. 4, a cross sectional view of the image sensor of FIG. 3 after a charge dissipation structure (grid/layer) has been formed is illustrated. As illustrated, the metal layer 14 is etched over the area of the pixel array to form a charge dissipation structure/layer/grid 16. In various implementations disclosed herein, the charge dissipation structure 16 is comprised within the ARC layer 4. In another implementation, the charge dissipation structure 16 may be embedded within the ARC layer 4. As a result, the charge dissipation structure 16 is formed into the plurality of trenches. In various implementations, a pixel array area is formed by the etching of the metal layer. The charge dissipation structure 16 may include an electrically conductive metal or other electrically conductive material. In such implementations, the electrically conductive metal/material collects electrostatic charges and, in some implementations, directs the electrostatic charges to an electrical ground. In various implementations, at least a portion of the charge dissipation structure 16 may contact, or be configured to contact, an electrically grounded pad through a grounding portion 18.

In other various implementations, the charge dissipation structure 16 may include a grid structure. In various implementations, as illustrated in FIG. 4, the grid structure or charge dissipation structure 16 is embedded within the ARC layer 4. The charge dissipation structure 16 may also surround the sides of the ARC layer 4. In various implementations, the grid structure may be formed in such a way as to minimize the line width, height, and/or position of the structure to minimize the impact on quantum efficiency (QE) of the overall image sensor itself. The process of etching back the metal layer 14 to form the charge dissipation structure 16 may provide improved pattern uniformity at the wafer processing level and may prevent collapse at the big pixel level. In various implementations, the grid structure or charge dissipation structure 16 may be made of, by non-limiting example, tungsten, aluminum, or a metallic oxide or nitride such as, but not limited to, TiO, TiN, TaN, or other metallic materials. In still other various implementations, the charge dissipation structure 16 may include a plurality of substantially parallel bars rather than a full or partial grid which form the charge dissipation structure 16.

Because of the optical transmissivity of the material of the charge dissipation layer, the charge dissipation structure (charge dissipation layer or charge dissipation grid) does not reduce the quantum efficiency (QE), or may only minimally reduce the QE of the image sensor. In various implementations, the charge dissipation structure may include, by non-limiting example, a conductive organic material, a carbon nanotube material, Ti, TiO₂, TiO, TiN, indium tin oxide (ITO), TaO, TaOₓ, any other electrically conductive material, or any combination thereof. In implementations of charge dissipation structures including a metal material, the charge dissipation structure may be optically transmissive due to the thickness of the layer or other materials included with the metal material within the charge dissipation layer. In implementations including a charge dissipation structure having a conductive organic material, the conductive organic material may include poly(3, 4-ethylenedioxythiophene):poly(styrenesulfonate) (PEDOT:PSS).

In various implementations of charge dissipation structures including a conductive organic material, the conductive organic material may be ink jet printed or spun onto a wafer in diluted form and then dried to remove the solvent. In implementations including metallic particles or metallic carbon nanotubes, the conductive materials may be suspended in a polymer forming suspension, such as, by non-limiting example, acrylics, polyimides, polyethylene, terephthalate, or polyesters. In particular implementations, the charge dissipation structures including conductive organic materials or metallic carbon nanotubes may be advantageous in implementations of image sensors and image sensor packages including charge dissipation structures above a color filter array (CFA) included in the sensor due to compatibility with the CFA or lens and due to the low temperature processing which may be necessary with image sensor back-end materials. The charge dissipation structure may be floating or may be electrically grounded. In implementations having a grounded charge dissipation structure, the charge dissipation structure may be coupled to one or more ground pads which may be included in the periphery of the image sensor.

In various implementations of the image sensors and image sensor packages disclosed herein, the charge dissipation structure may be a solid and continuous layer. In other implementations, any of the charge dissipation structure may be patterned into a grid, partial grid, or a plurality of lines. In such implementations, the center area of each pixel in the pixel array may be exposed through the grid as a mechanism for minimizing QE loss caused by the material of the charge dissipation structure. In implementations having a grid, the charge dissipation structure may or may not be optically transmissive as the material of the charge dissipation structure need not be transparent to the same wavelengths used to calculate the optimal sensor QE (which depends on the particular wavelength(s) of light the sensor is designed to detect). In implementations having a grid, the grid width may be as small as about 0.25 to about 1.0 um wide (for an about 1 um to an about 4 um pixel). In other implementations, the widths may be narrower than about 0.25 um or wider than about 1.0 um.

Various implementations of the image sensors and image sensor packages disclosed herein may include charge dissipation structures or structures capable of enabling charge dissipation and even distribution of charges resulting from ESD events, both air and direct contact discharge events, up to at least 30 kV in implementations where the charge dissipation structure is floating and not grounded.

The various implementations of image sensors and image sensor packages having charge dissipation structures disclosed herein has been observed to unexpectedly improve the observed dark signal ratio between the active array pixels and the optically black reference pixels. In such implementations, the ratio appears to be improved due to the charge dissipation structure ameliorating any charging of the pixel material accumulated during etching steps used to form the pixels in the fabrication process.

The various implementations of charge dissipation structures disclosed herein may have a minimal negative effect, and in some implementations no effect at all, on QE, indicating that the charge dissipation structure does not unduly affect light transmission (was sufficiently transparent or translucent). Further, the image sensors and image sensor packages disclosed herein may have a dark shading profile, or dark signal, that is more uniform across the entire image sensor array. The charge dissipation structures disclosed herein may also reduce the number of hot or white pixels and greatly decrease the dark signal non-uniformity (DSNU) of the various image sensors.

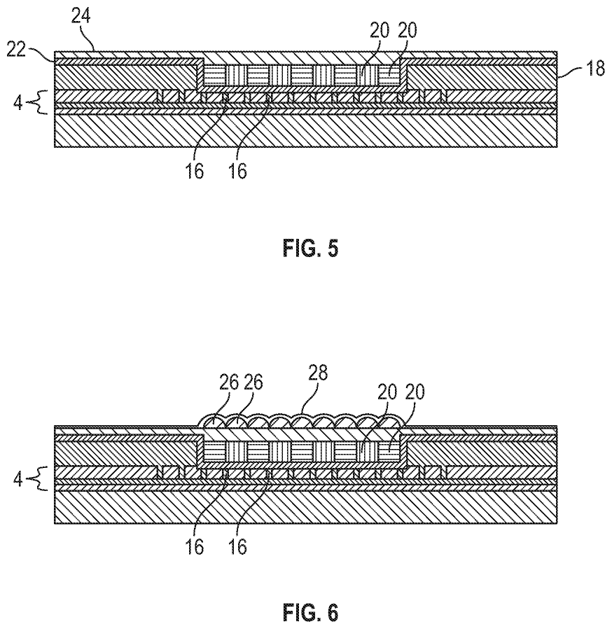

Referring to FIG. 5, a cross sectional view of the image sensor of FIG. 4 including a color filter array is illustrated. As illustrated, a color filter array 20 is coupled over passivation layer 22. In various implementations, the passivation layer 22 may include a first planarizing layer made of a polymer, or may be a pad cap layer. The passivation/planarizing layer 22 may also contact the grounding portion 18. As illustrated, the charge dissipation structure 16 may be included within the ARC layer 4, though only a portion of the charge dissipation structure 16 may be in contact with the passivation layer 22. As illustrated, a second planarizing/passivation layer 24 may be formed over the first planarizing layer 22. In various implementations, the second planarizing layer 24 may be made of a polymer. In various implementations, the first and second planarizing layers 22 and 24 may be made of the same material, which may, in various implementations, be, by non-limiting example, a polymer, a mixture of polymers, a resin, a filler, an additive, or any combination thereof. The first planarizing layer 22 may be a bottom planarizing layer (BPL) used in a CFA process. The second planarizing layer 24 may be a top planarizing layer (TPL) used in a microlens (uLens) process. As illustrated, the second planarizing layer 24 may be formed over the color filter array 20. Further, as disclosed herein, other implementations of image sensors may not include all of the layers disclosed, may include more than these layers, may include these layers in a different arrangement, or any combination thereof. The passivation/planarizing layers may also be, by non-limiting example, silicon oxide, silicon nitride, or any other passivation layer material type.

Referring to FIG. 6, a cross sectional view of the image sensor of FIG. 5 including a plurality of lenses (microlenses) is illustrated. As illustrated, a plurality of lenses 26 may be coupled over the color filter array 20. As illustrated, the portion of the image sensor that includes the lenses 26 and the color filter array 20 may be located over the portion of the image sensor that includes the charge dissipation structure 16 comprised within the ARC layer 4. As illustrated, a second antireflective coating (ARC) layer 28 may be formed over the plurality of lenses 26.

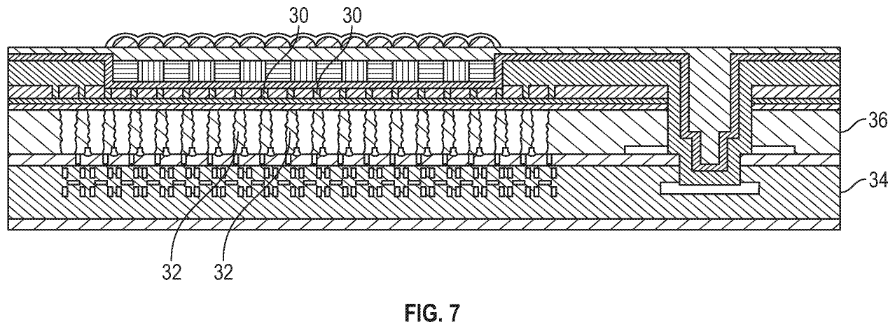

Referring to FIG. 7, a cross sectional view of the image sensor including two semiconductor die is illustrated. As illustrated, a pixel region 32 of the image sensor is coupled beneath the charge dissipation structure 30. In various implementations, as illustrated, the image sensor may include a first semiconductor die 34 and a second semiconductor die 36. In various implementations, the semiconductor dies may be bonded together using a fusion, hybrid, or other bonding technique. In other various implementations, the image sensor may include only one semiconductor die.

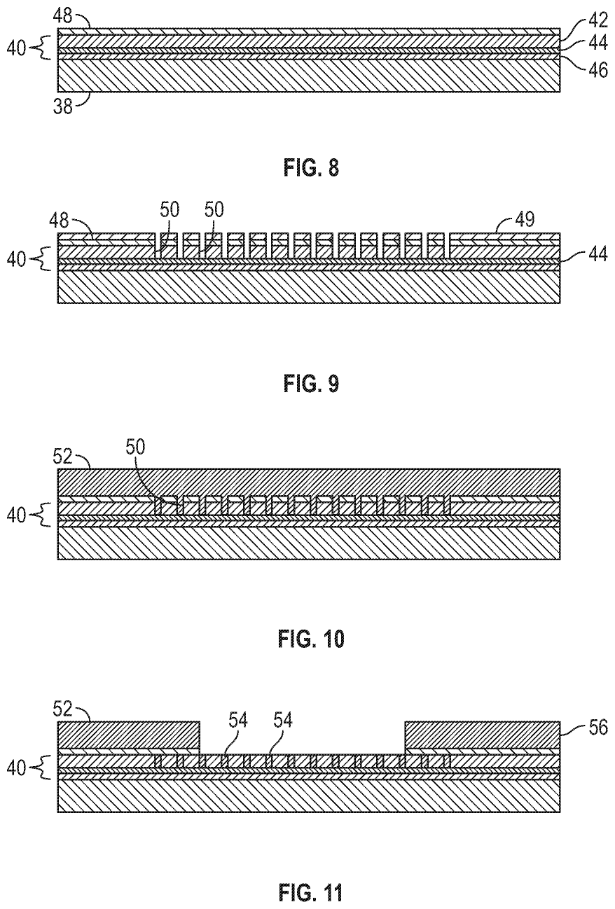

Referring to FIG. 8, a cross sectional view of another implementation of an image sensor including a hafnium oxide layer is illustrated. As illustrated, an antireflective coating (ARC) layer 40 is formed, or coupled, over a semiconductor substrate 38. While a semiconductor substrate is referred to herein, it is understood that the semiconductor substrate (layer) in any implementation disclosed herein could be any type of semiconductor substrate disclosed herein.

Still referring to FIG. 8, the ARC layer 40 may include a number of layers, as illustrated. In various implementations, the number of layers may vary; the ARC layer 40 may include a first layer 42, a second layer 44, and a third layer 46, though the number of layers may vary to any number of layers. In various implementations, the first layer 42 may include tantalum oxide (TaO). In various implementations, the second layer 44 may include hafnium oxide (HfO₂). In such implementations, the hafnium oxide may be configured to act as an etch stop. In various implementations, the third layer 46 may include aluminum oxide (Al₂O₃). As illustrated, the image sensor may also include a hafnium oxide layer (etch stop layer) 48 coupled over the ARC layer 40. This hafnium oxide layer 48 may be configured to act as an etch stop.

Referring to FIG. 9, a cross sectional view of the image sensor of FIG. 8 after the ARC layer 40 has been patterned is illustrated. As illustrated, the ARC layer 40 is coupled over the semiconductor substrate 38. After the ARC layer 40 has been patterned, a plurality of trenches 50 are formed within the ARC layer 40. As illustrated, and in implementations where the ARC layer 40 includes three layers, the ARC layer 40 is patterned, or etched, down through a photoresist layer 49 (which may be a photodefinable hard mask in some implementations) and the hafnium oxide layer 48 to the second layer 44. As previously disclosed, the second layer 44 may include hafnium oxide, which may act as an etch stop, which then selectively prevents etching of the ARC layer 40 past the second layer 44.

Referring to FIG. 10, a cross sectional view of the image sensor of FIG. 9 after a metal layer has been formed thereon is illustrated. As illustrated, a metal layer 52 is formed over the ARC layer 40 and into the plurality of trenches 50. In various implementations, the metal layer 14 may be deposited through, by non-limiting example, sputtering, chemical vapor deposition, a combination of physical vapor deposition and chemical vapor deposition, spin coating, ink-jet printing, screen printing, or any other process of forming an electrically conductive layer on the material over the ARC layer 40 material.

Referring to FIG. 11, a cross sectional view of the image sensor of FIG. 10 after a charge dissipation structure (layer) has been formed is illustrated. As illustrated, the metal layer 52 is etched to form a charge dissipation structure/layer/grid 54. In particular implementations, the charge dissipation structure 54 is included within the ARC layer 40. The charge dissipation structure 54 includes an electrically conductive metal/material like any disclosed in this document. In such implementations, the electrically conductive metal/material may be configured to collect electrostatic charges and to direct the electrostatic charges to a ground. In various implementations, at least a portion of the charge dissipation structure 54 may contact, or be configured to contact, a grounded pad through a grounding portion 56. In various implementations, the charge dissipation structure 54 may take on any structure as previously disclosed and described herein.

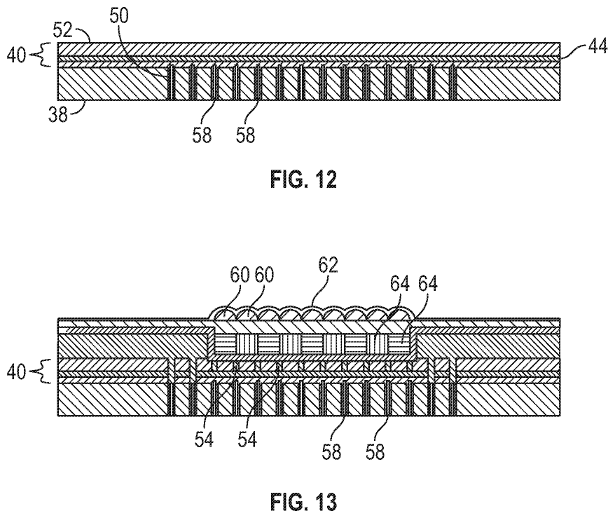

Referring to FIG. 12, a cross sectional view of the image sensor of FIG. 11 including a deep trench isolation structure is illustrated. As illustrated, each trench of the plurality of trenches 50 in the semiconductor substrate 38 is filled with one of a polysilicon or an electrically conductive material to form one of a backside/frontside deep trench isolation structure 58. As illustrated, the second layer 44 of the ARC layer 40 is coupled over the first layer 42 of the ARC layer 40. In various implementations, one or more trenches of the plurality of trenches 50 is extended entirely through the first layer 42 of the ARC layer 40, forming a connection with the deep trench isolation structure 58. In various implementations, an intermediate patterning process may include selectively etching the deep trench isolation structure 58 using a second etchant after the plurality of trenches 50 is etched using a first etchant, and before forming a metal layer into the trenches 50. In various implementations, this selective etching of the trenches may be performed using a photolithographic patterning process.

Referring to FIG. 13, a cross sectional view of the image sensor of FIG. 12 including a plurality of lenses (microlenses) is illustrated. As illustrated, a plurality of lenses 60 may be coupled over a color filter array 64. As illustrated, the portion of the image sensor that includes the lenses 60 and the color filter array 64 may be over the portion of the image sensor that includes the deep trench isolation structure 58 and the charge dissipation structure 54 comprised within the ARC layer 40. As illustrated, a second antireflective coating (ARC) layer 62 may be formed over the plurality of lenses 60. In this implementation, the electrostatic charges may be directed to ground through the connection between the charge dissipation structure 54 and the deep trench isolation structure 58 where the structure 58 is connected to a ground. In this way, the charge dissipation structure 54 may not be connected to a grounded pad, but may be connected to ground only through the deep trench isolation structure 58 in such implementations. In other implementations, the charge dissipation structure 54 may be floating or ungrounded as disclosed in this document.

In places where the description above refers to particular implementations of image sensors and implementing components, sub-components, methods and sub-methods, it should be readily apparent that a number of modifications may be made without departing from the spirit thereof and that these implementations, implementing components, sub-components, methods and sub-methods may be applied to other image sensors.

What is claimed is:

1. An image sensor comprising:
a semiconductor substrate;
an antireflective coating (ARC) layer coupled over the semiconductor substrate;
a charge dissipation structure comprised within the ARC layer; and
a passivation layer coupled over the ARC layer.

2. The image sensor of claim 1, further comprising a color filter array coupled over the passivation layer.

3. The image sensor of claim 2, further comprising a plurality of lenses coupled over the color filter array.

4. The image sensor of claim 1, further comprising a hafnium oxide layer coupled over the ARC layer.

5. The image sensor of claim 1, further comprising one of a backside deep trench isolation structure or a frontside deep trench isolation structure comprised within the semiconductor substrate.

6. The image sensor of claim 1, wherein the charge dissipation structure comprises an electrically conductive metal.

7. The image sensor of claim 6, wherein the electrically conductive metal is configured to collect electrostatic charges and to direct the electrostatic charges to a ground.

8. The image sensor of claim 1, wherein the charge dissipation structure comprises a grid.

9. The image sensor of claim 1, wherein the charge dissipation structure comprises a plurality of substantially parallel bars.

10. The image sensor of claim 1, wherein at least a portion of the charge dissipation structure contacts a grounded pad.

11. A method of forming an image sensor, comprising:
providing a semiconductor substrate;
forming an antireflective coating (ARC) layer over the semiconductor substrate;
patterning the ARC layer to form a plurality of trenches therein;
forming a charge dissipation layer into the plurality of trenches;
etching a pixel array area into the charge dissipation layer; and
forming a passivation layer over the ARC layer.

12. The method of claim 11, further comprising forming a color filter array over the passivation layer.

13. The method of claim 12, further comprising forming a plurality of lenses over the color filter array.

14. The method of claim 11, further comprising:
forming a hafnium oxide layer over the ARC layer; and
using the hafnium oxide layer as an etch stop during etching the pixel array area into the charge dissipation layer.

15. The method of claim 11, further comprising:
etching a plurality of trenches in the semiconductor substrate; and
filling each trench of the plurality of trenches with one of a polysilicon or an electrically conductive material to form one of a backside deep trench isolation structure or a frontside deep trench isolation structure.

16. The method of claim 15, wherein the ARC layer comprises at least a second layer coupled over a first layer and further comprising extending one or more trenches of the plurality of trenches entirely through the first layer of the ARC layer.

17. A method of forming an image sensor, comprising:
providing a semiconductor substrate;
forming an antireflective coating (ARC) layer over the semiconductor substrate;
forming an etch stop layer over the ARC layer;
patterning the ARC layer to form a plurality of trenches therein;
forming a charge dissipation layer into the plurality of trenches;
etching a pixel array area into the charge dissipation layer; and
forming a passivation layer over the ARC layer.

18. The method of claim 17, further comprising:
forming a color filter array over the passivation layer; and
forming a plurality of lenses over the color filter array.

19. The method of claim 17, further comprising:
etching a plurality of trenches in the semiconductor substrate; and
filling each trench of the plurality of trenches with one of a polysilicon or an electrically conductive material to form one of a backside deep trench isolation structure or a frontside deep trench isolation structure.

20. The method of claim 19, wherein the ARC layer comprises at least a second layer coupled over a first layer and further comprising extending one or more trenches of the plurality of trenches entirely through the first layer of the ARC layer.
